(19) United States
(12) Patent Application Publication
(10) Pub. No.: US 2025/0118660 A1
(43) Pub. Date: Apr. 10, 2025

(54) ELECTRONIC FUSE VIA AND LOGIC DEVICE CO-INTEGRATION WITH BACKSIDE POWER DELIVERY NETWORK

(71) Applicant: International Business Machines Corporation, Armonk, NY (US)

(72) Inventors: Manasa Medikonda, Albany, NY (US); Tao Li, Slingerlands, NY (US); Ruilong Xie, Niskayuna, NY (US); Nicolas Jean Loubet, Guilderland, NY (US)

(21) Appl. No.: 18/482,213

(22) Filed: Oct. 6, 2023

(51) Int. Cl. H01L 23/525; H01L 23/522; H01L 23/528

(52) U.S. Cl. CPC H01L 23/5256; H01L 23/5226; H01L 23/5286

(57) ABSTRACT

A semiconductor structure includes an electronic fuse via having a positive tapered shape extending from a back-end-of-the-line interconnect to a backside power delivery network. The electronic fuse via comprises a conductive material.

### BACKGROUND

To fabricate integrated circuits (ICs), such as memory devices and logic devices, having a high integration density, the industry generally downscales the dimensions of field effect transistors (FETs), such as metal-oxide-semiconductor field effect transistors (MOSFETs), and passive devices, such as semiconductor resistors and electronic fuses (efuses). Scaling achieves compactness and improves the operating performance in devices by shrinking the overall dimensions of the devices while maintaining the electrical properties of the devices. Generally, all the dimensions of a device are typically scaled in order to optimize its electrical performance.

### SUMMARY

Illustrative embodiments of the present application include techniques for use in semiconductor manufacture. In an illustrative embodiment, a semiconductor structure comprises an electronic fuse via having a positive tapered shape extending from a back-end-of-the-line interconnect to a backside power delivery network. The electronic fuse via comprises a conductive material.

According to another exemplary embodiment, a semiconductor structure comprises an electronic fuse via having a negative tapered shape extending from a back-end-of-the-line interconnect to a backside power delivery network. The electronic fuse via comprises a conductive material.

In a further exemplary embodiment, a semiconductor structure comprises an electronic fuse via extending from a back-end-of-the-line interconnect to a backside power delivery network. The electronic fuse via comprises a conductive material. The electronic fuse via comprises a void within the electronic fuse via.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 is a side cross-sectional view of a logic device and an electronic fuse region of a semiconductor structure for use at the first-intermediate fabrication stage, according to an illustrative embodiment.

FIG. 2 is a side cross-sectional view of the logic device and the electronic fuse region of the semiconductor structure for use at a second-intermediate fabrication stage, according to an illustrative embodiment.

FIG. 3 is a side cross-sectional view of the logic device and the electronic fuse region of the semiconductor structure for use at a third-intermediate fabrication stage, according to an illustrative embodiment.

FIG. 4 is a side cross-sectional view of the logic device and the electronic fuse region of the semiconductor structure for use at a fourth-intermediate fabrication stage, according to an illustrative embodiment.

FIG. 5 is a side cross-sectional view of the logic device and the electronic fuse region of the semiconductor structure for use at a fifth-intermediate fabrication stage, according to an illustrative embodiment.

FIG. 6 is a side cross-sectional view of the logic device and the electronic fuse region of the semiconductor structure for use at a sixth-intermediate fabrication stage, according to an illustrative embodiment.

FIG. 7 is a side cross-sectional view of the logic device and the electronic fuse region of the semiconductor structure for use at a seventh-intermediate fabrication stage, according to an illustrative embodiment.

FIG. 8 is a side cross-sectional view of the logic device and the electronic fuse region of the semiconductor structure for use at an eighth-intermediate fabrication stage, according to an illustrative embodiment.

FIG. 9 is a side cross-sectional view of the logic device and the electronic fuse region of the semiconductor structure for use at a ninth-intermediate fabrication stage, according to an illustrative embodiment.

FIG. 10 is a side cross-sectional view of the logic device and the electronic fuse region of the semiconductor structure for use at a tenth-intermediate fabrication stage, according to an illustrative embodiment.

FIG. 11 is a side cross-sectional view of the logic device and the electronic fuse region of the semiconductor structure for use at an eleventh-intermediate fabrication stage, according to an illustrative embodiment.

FIG. 12 is a side cross-sectional view of the logic device and the electronic fuse region of the semiconductor structure for use at a twelfth-intermediate fabrication stage, according to an illustrative embodiment.

FIG. 13 is a side cross-sectional view of the logic device and the electronic fuse region of the semiconductor structure for use at a thirteenth-intermediate fabrication stage, according to an illustrative embodiment.

FIG. 14 is a side cross-sectional view of the logic device and the electronic fuse region of the semiconductor structure prepared in FIGS. 1-13, according to an alternative illustrative embodiment.

FIG. 15 is a side cross-sectional view of a logic device and an electronic fuse region of a semiconductor structure for use at a first-intermediate fabrication stage, according to an alternative illustrative embodiment.

FIG. 16 is a side cross-sectional view of the logic device and the electronic fuse region of the semiconductor structure for use at a second-intermediate fabrication stage, according to an alternative illustrative embodiment.

FIG. 17 is a side cross-sectional view of the logic device and the electronic fuse region of the semiconductor structure for use at a third-intermediate fabrication stage, according to an alternative illustrative embodiment.

FIG. 18 is a side cross-sectional view of the logic device and the electronic fuse region of the semiconductor structure prepared in FIGS. 15-17, according to an alternative illustrative embodiment.

### DETAILED DESCRIPTION

This disclosure relates generally to semiconductor devices, and more particularly to semiconductor structures having an electronic fuse (“efuse”) via extending from a back-end-of-the-line structure to a backside power delivery network where the efuse via includes high resistance conductive materials within the efuse via, and methods for their fabrication. However, it is to be understood that embodiments of the present disclosure are not limited to the illustrative methods, apparatus, systems and devices but instead are more broadly applicable to other suitable methods, apparatus, systems and devices.

An efuse allows for the dynamic real-time reprogramming of chips. By utilizing a set of efuses, a chip manufacturer can allow for the circuits on a chip to change while it is in operation. In general, traditional efuses can be inserted in either of a back-end-of-line metallization levels M1 or M2. However, with power lines moving to the backside as in a backside power delivery network, there is a need to incorporate efuse flow that is compatible with a logic device as well as a backside power delivery network scheme.

The non-limiting illustrative embodiments described herein overcome the foregoing drawbacks by providing a semiconductor structure comprising an electronic fuse via having either a positive tapered shape extending from a back-end-of-the-line interconnect to a backside power delivery network, or a negative tapered shape extending from a back-end-of-the-line interconnect to a backside power delivery network, where the electronic fuse via comprises a conductive material. In addition, the non-limiting illustrative embodiments provide for the co-integration of the electronic fuse via with a logic device. For example, the electronic fuse via can be co-integrated with the logic device through one or more of backside contacts and a backside power delivery network thereby allowing for the manufacturer to change circuits while in operation.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

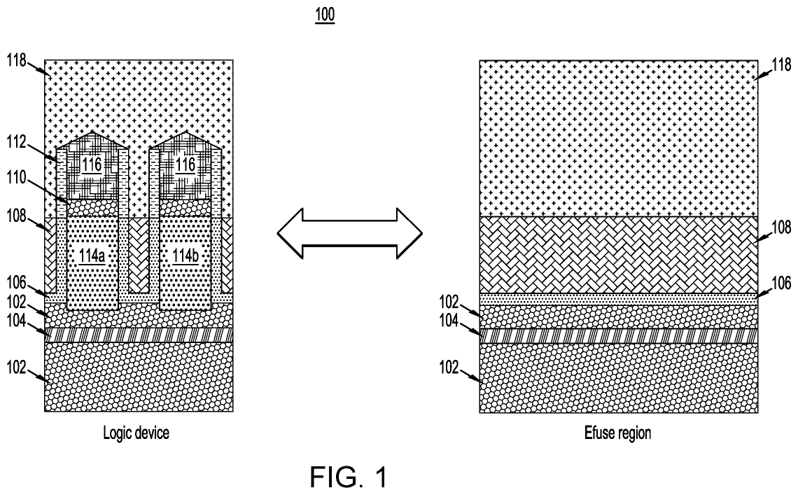

Referring now to the drawings in which like numerals represent the same of similar elements, FIGS. 1-18 illustrate various processes for fabricating semiconductor structures with efuse via structures. Note that the same reference numeral (100) is used to denote the semiconductor structure through the various intermediate fabrication stages illustrated in FIGS. 1-18. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1-18 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIG. 1 shows a side cross-sectional view of the logic device and the electronic fuse region of the semiconductor structure 100 for use at the first-intermediate fabrication stage.

Semiconductor structure 100 includes a substrate 102. The substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

An etch stop layer 104 is formed in the substrate 102. The etch stop layer 104 may comprise a buried oxide (BOX) layer or silicon germanium (SiGe), or another suitable material such as a III-V semiconductor epitaxial layer.

A shallow trench isolation (STI) liner 106 is formed on substrate 102 and sidewalls of sacrificial placeholder 114a and 114b. Suitable materials for STI liner 106 include, for example, SiCO, SiOCN and silicon nitride (SiN).

Semiconductor structure 100 further includes STI region 108 disposed on STI liner 106. STI region 108 comprises a dielectric material such as silicon oxide or silicon oxynitride, and is formed by methods known in the art. For example, in one illustrative embodiment, STI region 108 is a shallow trench isolation oxide layer.

Semiconductor structure 100 further includes nanosheet channel layer 110, which may be formed of Si, epitaxial SiGe material or another suitable material (e.g., a material similar to that used for the substrate 102).

Semiconductor structure 100 further includes sacrificial placeholders 114a and 114b formed below source/drain regions 116 having sidewall spacers 112. Sacrificial placeholders 114a and 114b may be formed of a sacrificial material or materials, such as SiGe, titanium oxide (TiOₓ), aluminum oxide (AlOₓ), silicon carbide (SiC), etc.

The sidewall spacers 112 may be formed of any suitable insulator, such as SiN, silicon boron carbide nitride (SiBCN), silicon oxycarbonitride (SiOCN), etc.

The source/drain regions 116 may be formed using epitaxial growth processes. The source/drain regions 116 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxy process comprises in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³.

Semiconductor structure 100 further includes interlevel dielectric (ILD) layer 118. ILD layer 118 may be formed of any suitable isolating material, such as SiO₂, SiOC, SiON, etc.

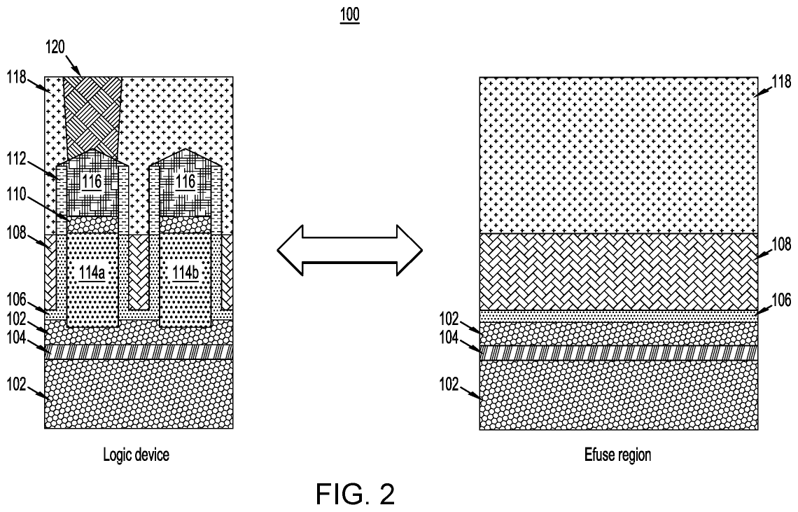

FIG. 2 shows semiconductor structure 100 at a second-intermediate fabrication stage. During this stage, middle-of-the-line contact 120 is formed in ILD layer 118 of the logic device by patterning and etching a via in the ILD layer 118. A suitable conductive metal is then deposited in the via to form middle-of-the-line contact 120. The conductive metal is deposited by conventional deposition processes such as PVD, ALD, CVD, and/or plating. The conductive metal can be any suitable conductive material such as, for example, tungsten (W), aluminum (Al), copper (Cu), cobalt (Co), nickel (Ni), titanium (Ti), ruthenium (Ru), molybdenum (Mo), or any other suitable conductive material.

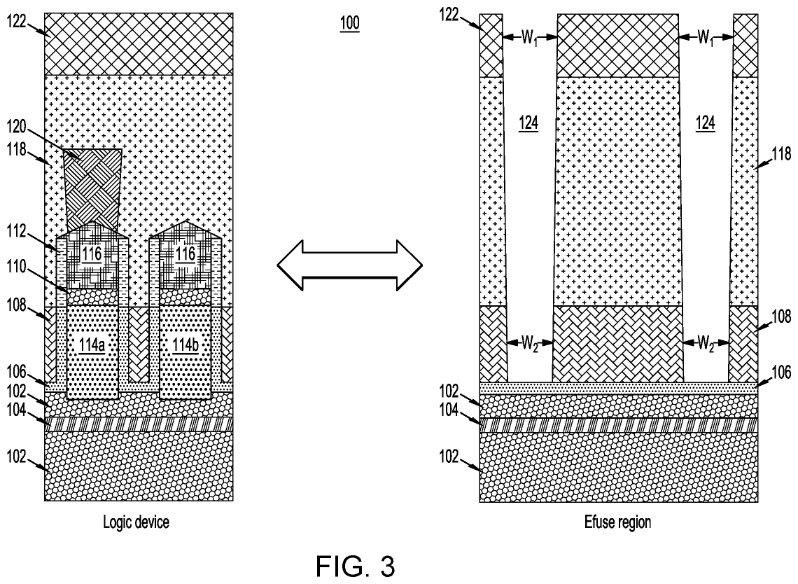

FIG. 3 shows semiconductor structure 100 at a third-intermediate fabrication stage. During this stage, an additional amount of ILD layer 118 is deposited by conventional deposition processes such as PVD, ALD, CVD, etc., and then a mask layer 122 (such as an organic planarization layer (OPL) or a spin-on-carbon (SOC)) is formed on ILD layer 118 using any conventional deposition process such spin-on coating or any other suitable deposition process.

Next, efuse vias 124 are formed in mask layer 122 and ILD layer 118 in the efuse region of semiconductor structure 100 to expose STI liner 106. Efuse vias 124 can be formed by utilizing conventional lithographic and selective etch processes such as a wet or dry etch etching process in mask layer 122 and ILD layer 118. In an illustrative embodiment, the etching process can be controlled to form such that efuse vias 124 are formed having a positive tapered shape, i.e., the tops of efuse vias 124 are wider in width than the width of the bottoms of efuse vias 124 as viewed in the cross section. In an illustrative embodiment, efuse vias 124 are formed having a width, W1, of an upper portion of the efuse vias 124 that is greater than a width, W2, of a lower portion of the efuse vias 124.

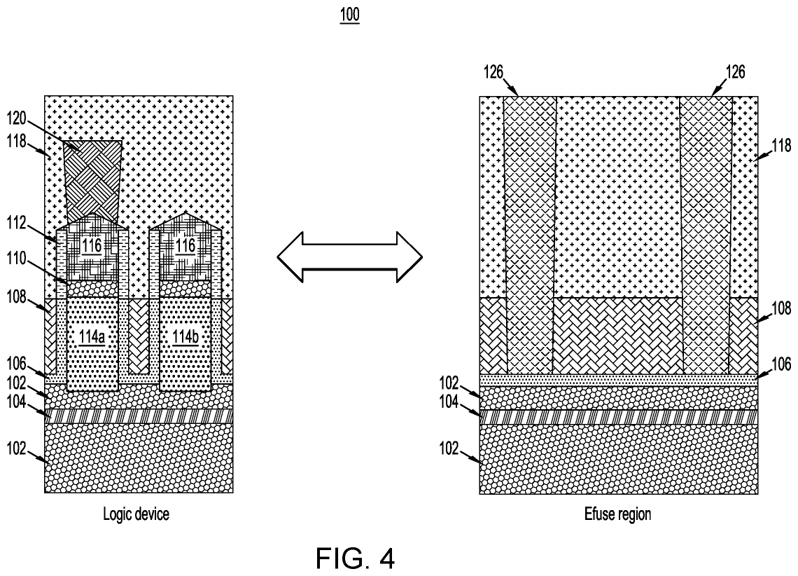

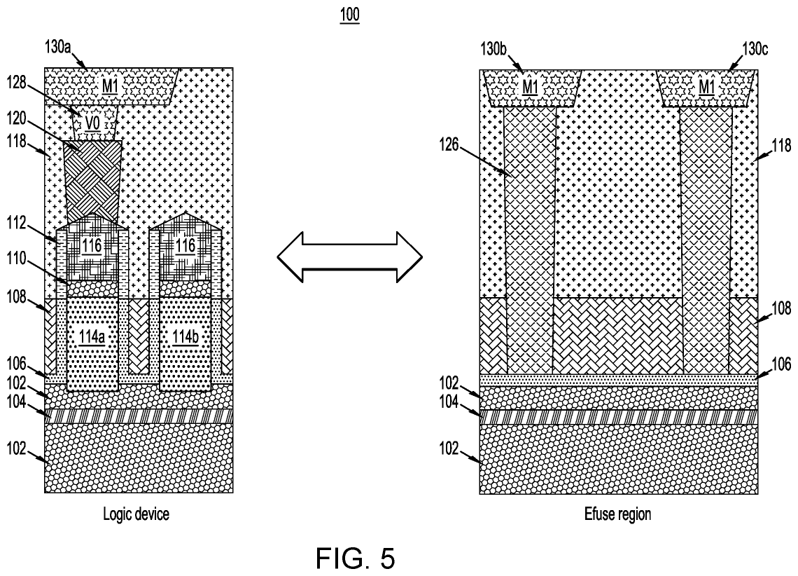

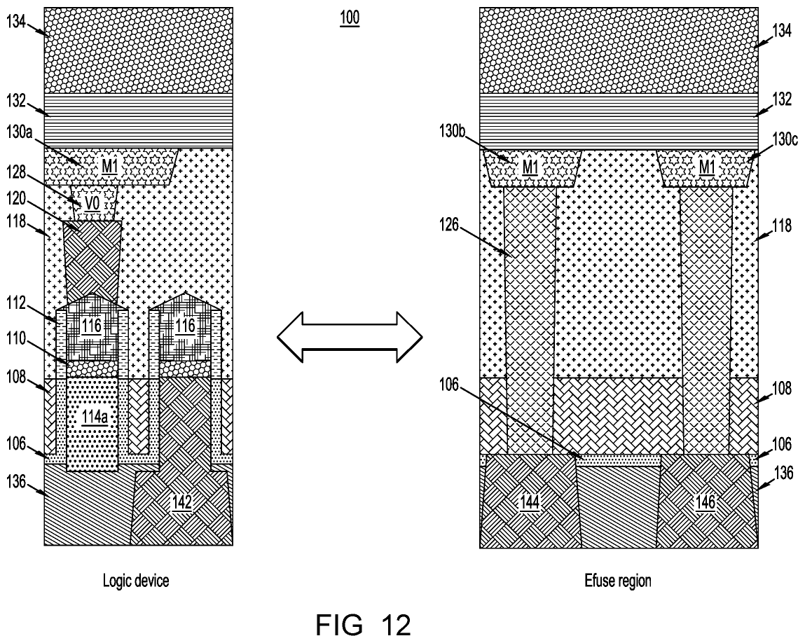

FIG. 4 shows semiconductor structure 100 at a fourth-intermediate fabrication stage. During this stage, a conductive material is deposited in efuse vias 124 to form efuse vias 126. In an illustrative embodiment, a conductive material can be a high resistance conductive material. For example, a high resistance conductive material in efuse vias 126 is typically much less conductive than the conductive material in the conductive metal lines 130b and 130c (FIG. 5) and backside middle-of-the-line contacts 144 and 146 (FIG. 12) to which the efuse vias 126 are connected to as discussed below. In an illustrative material, the conductive material for efuse vias 126 has a first resistance and the conductive material for conductive metal lines 130b and 130c (FIG. 5) and backside middle-of-the-line contacts 144 and 146 each have a second resistance lower than the first resistance. For example, the high resistance conductive material can have about 5×, or about 10× and up to about 100× higher resistance than a conductive material for conductive metal lines 130b and 130c (FIG. 5) and backside middle-of-the-line contacts 144 and 146. These materials are known in the art and commercially available. Suitable high resistance conductive material includes, for example, high resistance conductive materials such as poly-Si, or silicided poly-Si or any other high resistance conductive materials including titanium nitride (TiN), tantalum nitride (TaN), and combinations thereof. The high resistance conductive material can be deposited by conventional techniques such as ALD, PVD and the like.

FIG. 5 shows semiconductor structure 100 at a fifth-intermediate fabrication stage. During this stage, metallization level M1 and via level VO are formed in logic device and metallization level M1 is formed in the efuse region of semiconductor structure 100. In general, the metal lines (also referred to as wiring lines) provide electrical connections within the same metal level, and conductive vias provide inter-level or vertical connections between different (metal) line levels. The conductive metal lines 130a, 130b and 130c for metallization level M1 and metal via 128 for via level VO are typically formed by etching a recess in a layer of dielectric material and filling the recess with a metal such as copper, tungsten, aluminum, etc. Typically, the conductive vias (i.e., a via level VO) are used to establish an electrical connection between the metal lines and the underlying device level contacts (e.g., middle-of-the-line contact 120).

To form metallization level M1 and via level VO in logic device and metallization level M1 in the efuse region of semiconductor structure 100, an additional ILD layer 118 is first deposited on semiconductor structure 100 by conventional deposition processes such as PVD, ALD, CVD, etc., followed by patterning and etching vias in the exposed ILD layer 118. A suitable conductive metal is then deposited in the vias to form a metal via 128 and conductive metal line 130a in logic device of semiconductor structure 100. A suitable conductive metal is also deposited in the vias to form conductive metal lines 130b and 130c in the efuse region of semiconductor structure 100. A suitable conductive metal can be deposited in a similar manner and of similar conductive metal as discussed above.

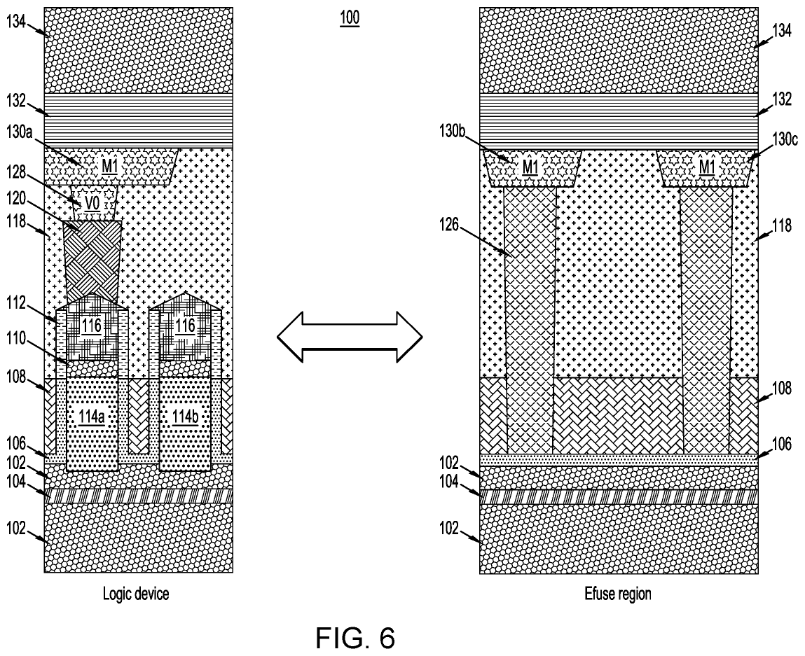

FIG. 6 shows semiconductor structure 100 at a sixth-intermediate fabrication stage. During this stage, frontside back-end-of-line (BEOL) interconnect 132 is formed followed by bonding of the structure (e.g., the frontside BEOL interconnect 132) to a carrier wafer 134. The frontside BEOL interconnect 132 includes various BEOL interconnect structures. For example, frontside BEOL interconnect 132 is a metallization structure that includes one or more metal layers disposed on a side of semiconductor structure 100 opposite of the side on which the backside BEOL metallization structure is disposed. The metal layers of the frontside BEOL interconnect 132 each have metal lines for making interconnections to the semiconductor device.

The carrier wafer 134 may be formed of materials similar to that of the substrate 102, and may be formed over the frontside BEOL interconnect 132 using a wafer bonding process, such as dielectric-to-dielectric bonding.

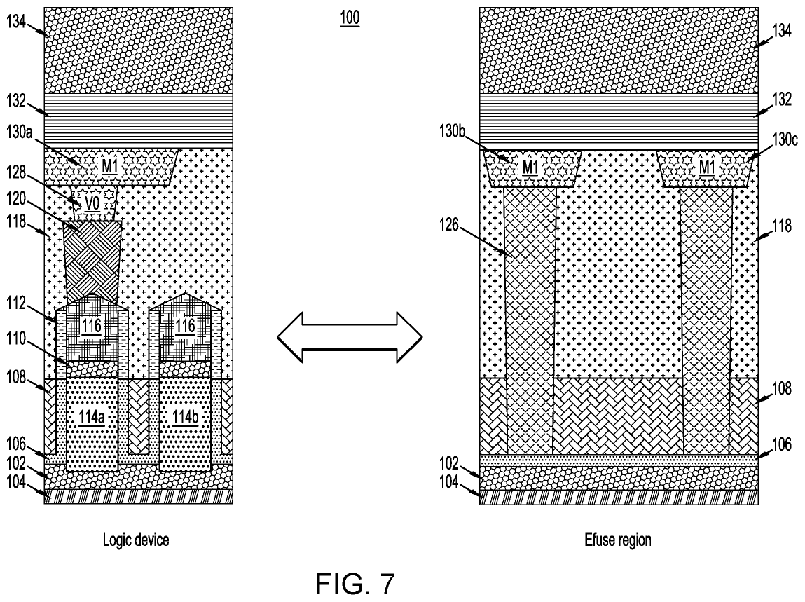

FIG. 7 shows semiconductor structure 100 at a seventh-intermediate fabrication stage. During this stage, portions of the substrate 102 may be removed from the backside by, for example, using the carrier wafer 134 and flipping the structure over so that the backside of the substrate 102 (i.e., the back surface) is facing up for backside processing. Next, portions of the substrate 102 may be removed from the backside using, for example, a wet etch to selectively remove substrate 102 until the etch stop layer 104 is reached.

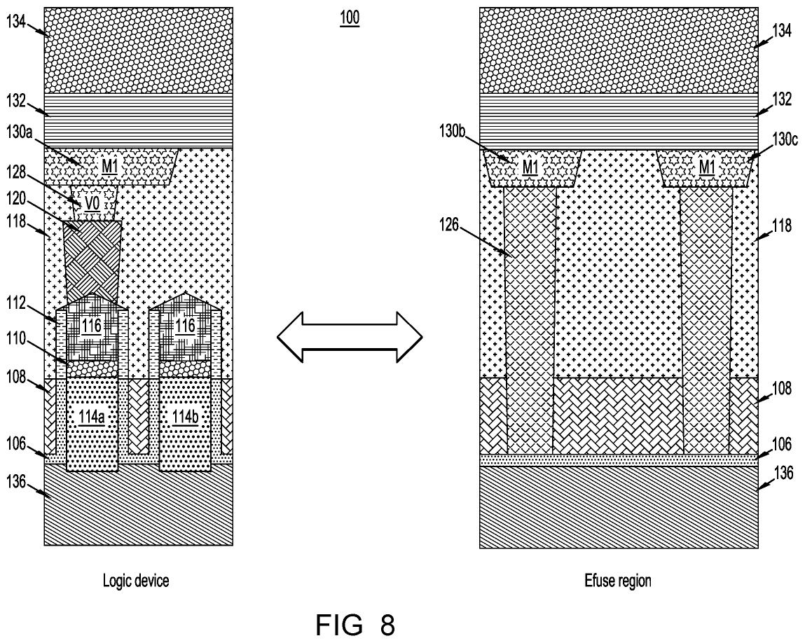

FIG. 8 shows semiconductor structure 100 at an eighth-intermediate fabrication stage. During this stage, the etch stop layer 104 is selectively removed using, for example, a wet etch to selectively remove etch stop layer 104 until substrate 102 is reached. The remaining portions of the substrate 102 are removed utilizing a selective etch process such as a wet etch to expose STI liner 106 and sacrificial placeholders 114a and 114b.

Next, backside ILD layer 136 may be formed of similar processes and material as ILD layer 118. The material of the backside ILD layer 136 may initially be overfilled, followed by planarization (e.g., using a chemical mechanical planarization (CMP) process).

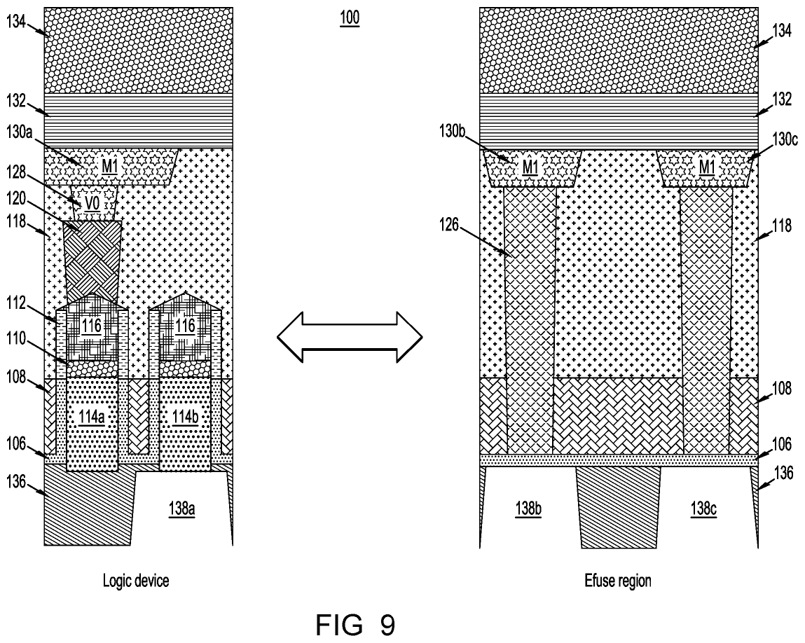

FIG. 9 shows semiconductor structure 100 at a ninth-intermediate fabrication stage. During this stage, backside middle-of-the-line contact opening 138a is formed in logic device, and backside middle-of-the-line contact openings 138b and 138c are formed in the efuse region. Backside middle-of-the-line contact openings 138a, 138b and 138c can be formed by first patterning and etching lines in the exposed backside ILD layer 136 to expose sacrificial placeholder 114b in logic device and STI liner 106 in the efuse region using any suitable wet or dry etch.

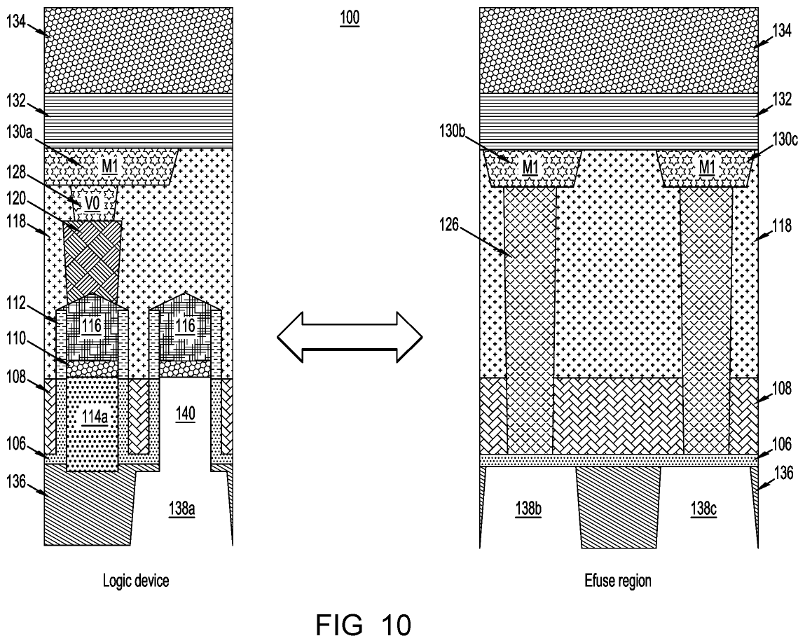

FIG. 10 shows semiconductor structure 100 at a tenth-intermediate fabrication stage. During this stage, sacrificial placeholder 114b is selectively removed to extend backside middle-of-the-line contact opening 138a as backside middle-of-the-line contact openings 138a and 140 using any suitable etch processing that removes the material of the sacrificial placeholder 114b selective to that of the rest of the structure. A suitable etching process includes, for example, a wet etch. The etching process exposes nanosheet channel layer 110.

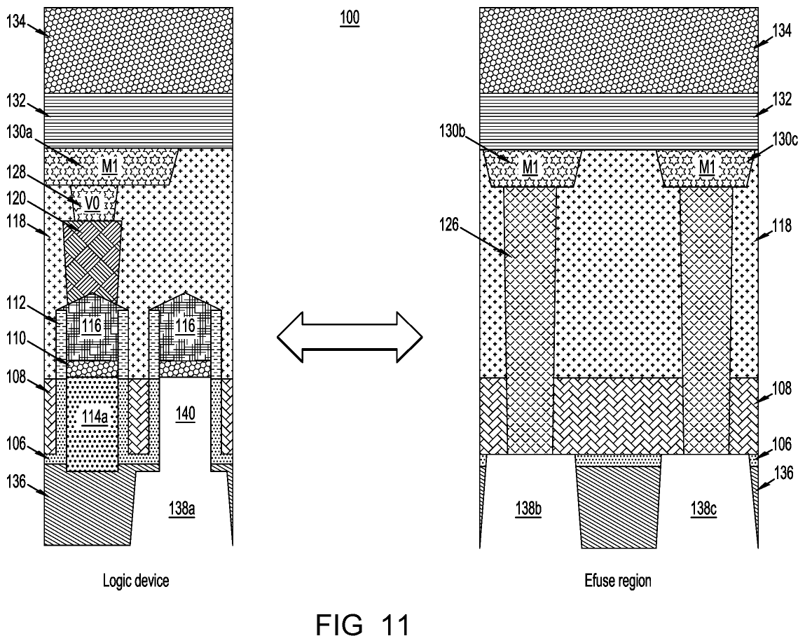

FIG. 11 shows semiconductor structure 100 at an eleventh-intermediate fabrication stage. During this stage, the exposed STI liner 106 in backside middle-of-the-line contact openings 138b and 138c of efuse region are selectively removed using any suitable etch processing that removes the material of the STI liner 106 selective to that of the rest of the structure. A suitable etching process includes, for example, a wet etch. The etching process exposes efuse vias 126.

FIG. 12 shows semiconductor structure 100 at a twelfth-intermediate fabrication stage. During this stage, a suitable conductive metal is then deposited in backside middle-of-the-line contact openings 138a and 140 of logic device, followed by CMP to remove any metal on top of backside ILD layer 136 to form backside middle-of-the-line contact 142. A suitable conductive metal is also deposited in backside middle-of-the-line contact openings 138b and 138c, followed by CMP to remove any metal on top of backside ILD layer 136 to form backside middle-of-the-line contacts 144 and 146. A suitable conductive metal can be deposited in a similar manner and of similar conductive metal as discussed above.

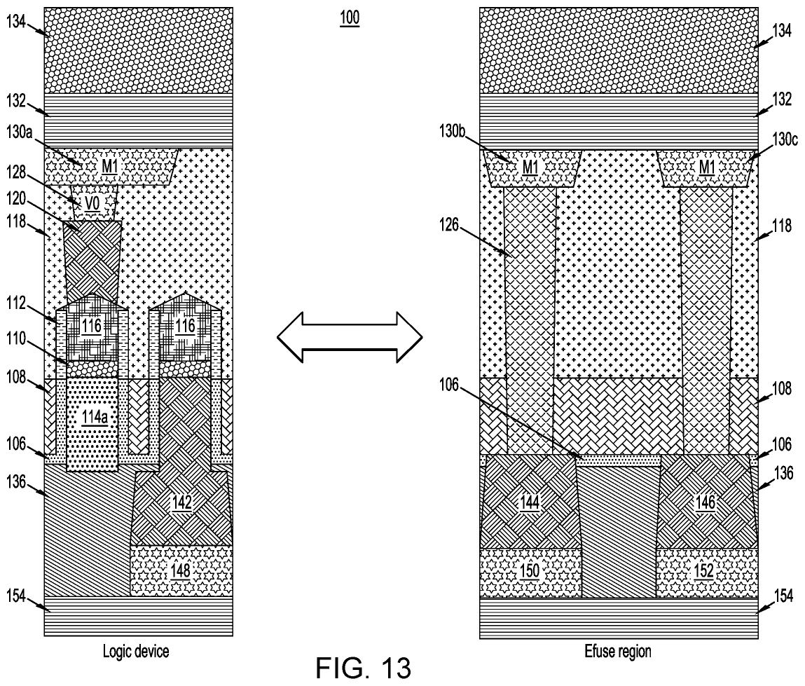

FIG. 13 shows semiconductor structure 100 at a thirteenth-intermediate fabrication stage. During this stage, backside power rail 148 is formed in logic device and backside power rails 150 and 152 are formed in the efuse region, followed by forming backside power delivery network 154. Backside power rails 148, 150 and 152 can be formed by depositing additional backside ILD layer 136 on semiconductor structure 100, followed by selectively removing backside ILD layer 136 to form backside power rail openings (not shown) and exposing backside middle-of-the-line contacts 142, 144 and 146 by, for example, an isotropic etch back. A suitable conductive metal is then deposited in the backside power rail openings, followed by CMP to remove any metal on top of backside ILD layer 136 to form backside power rails 148, 150 and 152. A suitable conductive metal can be deposited in a similar manner and of similar conductive metal as discussed above.

Backside power delivery network 154 is formed over the structure including backside power rails 148, 150 and 152 and is based on creation of a wiring scheme that is disposed on both sides of the device layer (front end of line structure). In illustrative embodiments, the efuse region can be co-integrated with the logic device through backside power rails 148, 150 and 152 and backside power delivery network 154 and this allows for the manufacturer to change circuits while in operation.

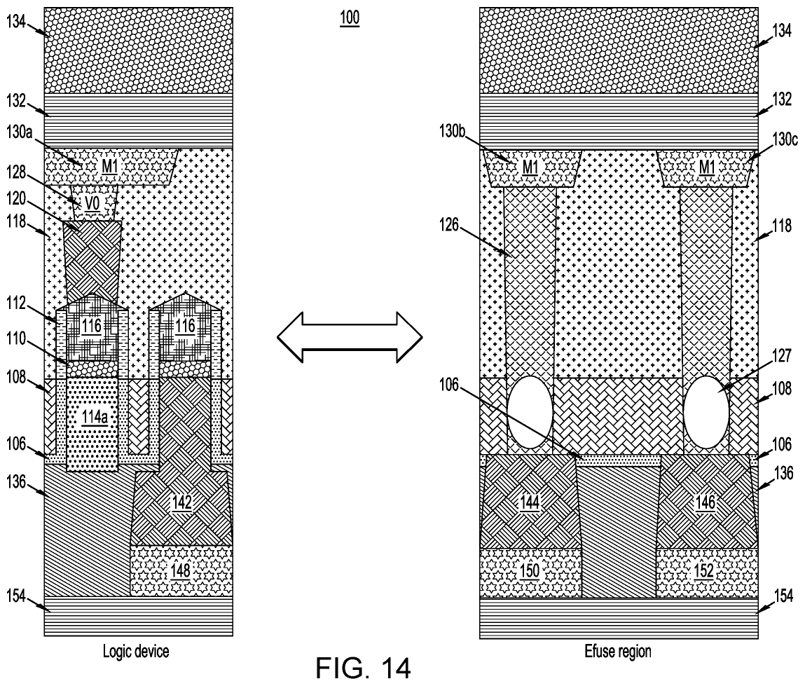

In illustrative embodiments, void 127 may be formed in the efuse vias 126 during deposition. Accordingly, FIG. 14 shows an alternate illustrative embodiment of semiconductor structure 100 of FIGS. 1-13 where void 127 is located within the efuse vias 126. In an illustrative embodiment, void 127 is located in proximity to backside power delivery network 154. In an illustrative embodiment, void 127 is located in proximity to backside power rails 150 and 152 in the efuse region.

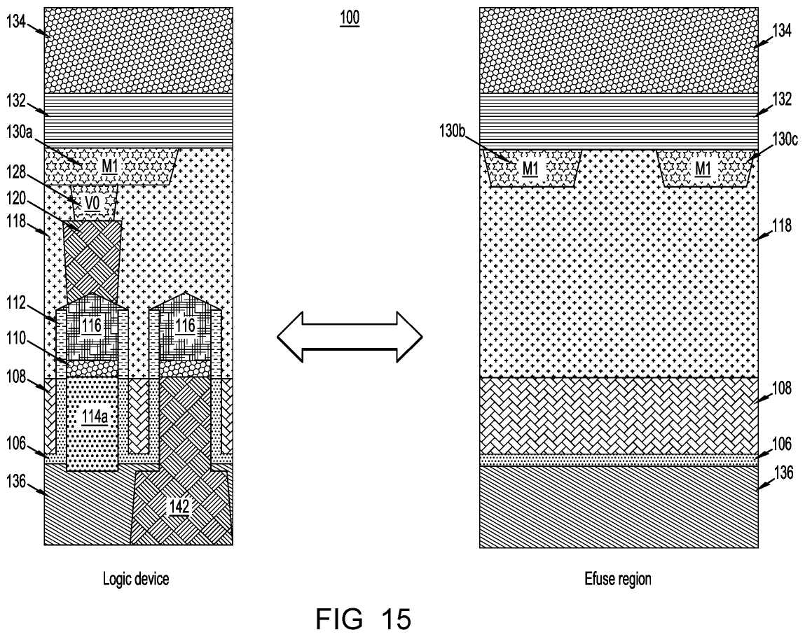

FIGS. 15-18 illustrate an alternative embodiment forming efuse vias 126 in semiconductor structure 100. FIG. 15 shows semiconductor structure 100 at a first-intermediate fabrication stage. Starting from FIG. 8 in which the steps shown in FIGS. 1-8 are carried out to form the same logic device, whereas the steps shown in FIGS. 1-8 to form the efuse region are carried out with the exception that the efuse vias 126 are not formed during these steps in this embodiment. In other words, the steps for forming efuse via 124 in FIG. 3 and the subsequent deposition of conductive metal in efuse via 124 to form efuse via 126 are not employed during these steps in this embodiment.

Turning to FIG. 15, backside middle-of-the-line contact 142 is formed in logic device as discussed above by first patterning and etching a backside middle-of-the-line contact opening in the exposed backside ILD layer 136 to expose sacrificial placeholder 114b. Sacrificial placeholder 114b is then selectively removed to extend backside middle-of-the-line contact opening using any suitable etch processing that removes the material of the sacrificial placeholder 114b selective to that of the rest of the structure. The etching process exposes nanosheet channel layer 110. A suitable conductive metal is then deposited in backside middle-of-the-line contact openings 138a and 140 of logic device, followed by CMP to remove any metal on top of backside ILD layer 136 to form backside middle-of-the-line contact 142. A suitable conductive metal can be deposited in a similar manner and of similar conductive metal as discussed above.

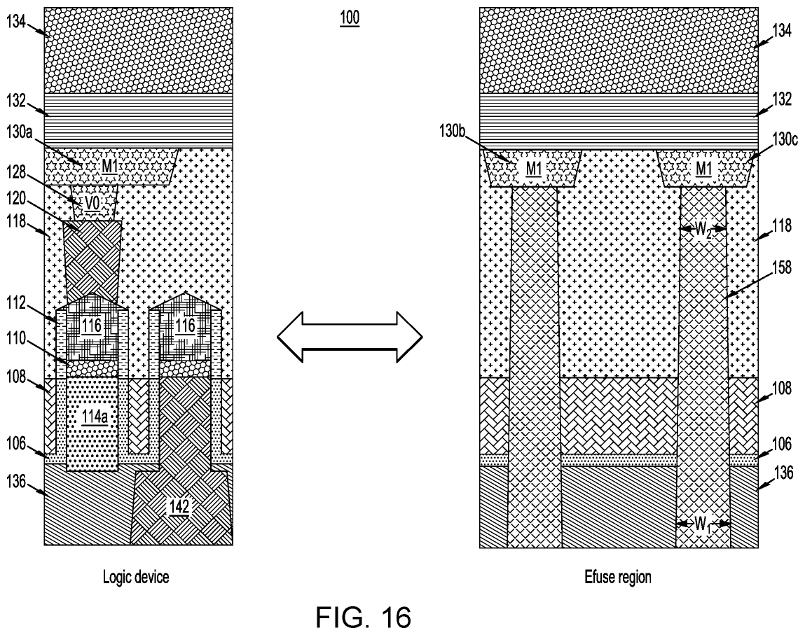

FIG. 16 shows semiconductor structure 100 at a second-intermediate fabrication stage. During this stage, efuse vias 158 are formed in the efuse region of semiconductor structure 100. For example, efuse vias 158 can be formed by standard lithographic and selective etch processes such as a wet or dry etch etching process in which efuse vias are formed through backside ILD layer 136, STI liner 106, STI region 108 and ILD layer 118 to expose conductive metal lines 130b and 130c. A high resistance conductive material as discussed above with respect to efuse vias 126 is deposited in the efuse vias to form efuse vias 158. In an illustrative embodiment, the etching process can be controlled such that the efuse vias 158 are formed having a negative tapered shape, i.e., the tops of efuse vias 158 are less in width than the widths of the bottoms of efuse vias 158 as viewed in the cross section. In an illustrative embodiment, efuse vias 158 are formed having a width, W1, of a lower portion of the efuse vias 158 that is greater than a width, W2, of an upper portion of the efuse vias 158.

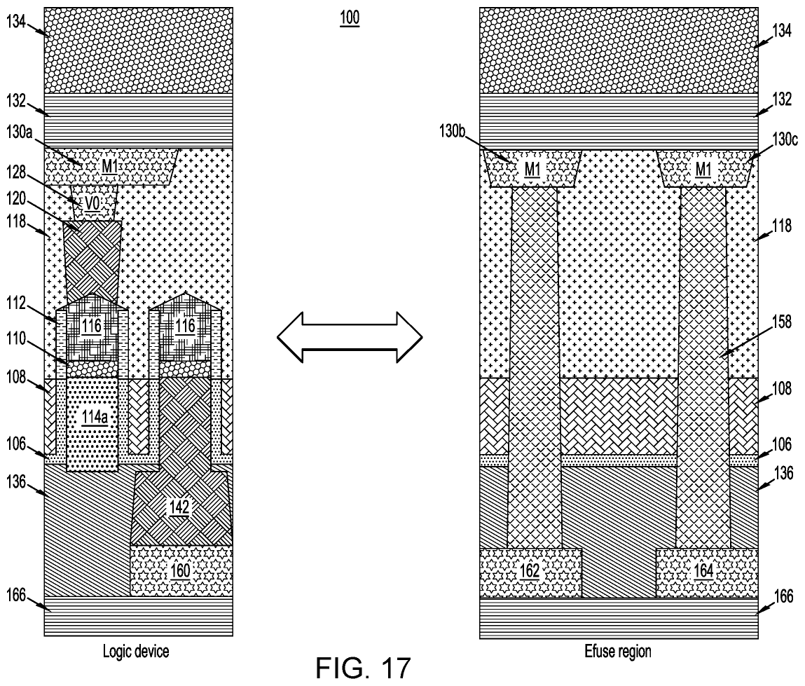

FIG. 17 shows semiconductor structure 100 at a third-intermediate fabrication stage. During this stage, backside power rail 160 is formed in logic device and backside power rails 162 and 164 are formed in the efuse region, followed by forming backside power delivery network 166. Backside power rails 160, 162 and 164 can be formed by depositing additional backside ILD layer 136 on semiconductor structure 100, followed by selectively removing backside ILD layer 136 to form backside power rail openings (not shown) and exposing backside middle-of-the-line contact 142 and efuse vias 158 by, for example, an isotropic etch back. A suitable conductive metal is then deposited in the backside power rail openings, followed by CMP to remove any metal on top of backside ILD layer 136 to form backside power rails 160, 162 and 164. A suitable conductive metal can be deposited in a similar manner and of similar conductive metal as discussed above.

Backside power delivery network 166 is formed over the semiconductor structure 100 including backside power rails 160, 162 and 164 and is based on creation of a wiring scheme that is disposed on both sides of the device layer (front end of line structure). In illustrative embodiments, the efuse region can be co-integrated with the logic device through backside power rails 160, 162 and 164 and backside power delivery network 166 and this allows for the manufacturer to change circuits while in operation.

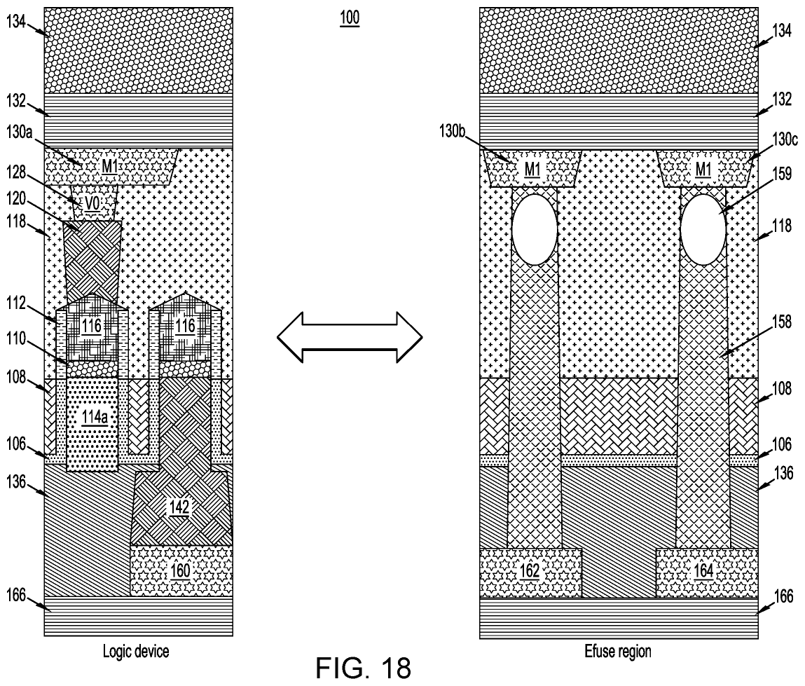

In illustrative embodiments, void 159 may be formed in the efuse vias 158 during deposition. Accordingly, FIG. 18 shows an alternate illustrative embodiment of semiconductor structure 100 of FIGS. 15-17 where void 159 is located within efuse vias 158. In an illustrative embodiment, void 159 is located in proximity to frontside BEOL interconnect 132 in the efuse region.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
an electronic fuse via having a positive tapered shape extending from a back-end-of-the-line interconnect to a backside power delivery network;
wherein the electronic fuse via comprises a conductive material.

2. The semiconductor structure according to claim 1, wherein the positive tapered shape of the electronic fuse via comprises an upper portion connected to the back-end-of-the-line interconnect having a first width and lower portion connected to the backside power delivery network having a second width less than the first width.

3. The semiconductor structure according to claim 1, wherein the electronic fuse via is connected to the back-end-of-the-line interconnect through a first conductive metal line of a metallization layer, and the electronic fuse via is connected to the backside power delivery network through a first backside middle-of-the-line contact.

4. The semiconductor structure according to claim 3, wherein the first backside middle-of-the-line contact is connected to the backside power delivery network through a first backside power rail.

5. The semiconductor structure according to claim 2, wherein the upper portion of the electronic fuse via is connected to the back-end-of-the-line interconnect through a conductive metal line of a metallization layer, and the lower portion of the electronic fuse via is connected to the backside power delivery network through a backside middle-of-the-line contact.

6. The semiconductor structure according to claim 5, wherein the backside middle-of-the-line contact is connected to the backside power delivery network through a backside power rail.

7. The semiconductor structure according to claim 1, wherein the conductive material comprises a poly-Si, or silicided poly-Si material.

8. The semiconductor structure according to claim 3, further comprising another electronic fuse via having a positive tapered shape extending from the back-end-of-the-line interconnect to the backside power delivery network; wherein the other electronic fuse via comprises another conductive material.

9. The semiconductor structure according to claim 8, wherein the other electronic fuse via is connected to the back-end-of-the-line interconnect through a second conductive metal line of the metallization layer, and the other electronic fuse via is connected to the backside power delivery network through a second backside middle-of-the-line contact.

10. The semiconductor structure according to claim 1, wherein the electronic fuse via is co-integrated with a logic device through the backside power delivery network.

11. The semiconductor structure according to claim 9, wherein the second backside middle-of-the-line contact is connected to the backside power delivery network through a second backside power rail.

12. A semiconductor structure, comprising:
an electronic fuse via having a negative tapered shape extending from a back-end-of-the-line interconnect to a backside power delivery network;
wherein the electronic fuse via comprises a conductive material.

13. The semiconductor structure according to claim 12, wherein the negative tapered shape of the electronic fuse via comprises an upper portion connected to the back-end-of-the-line interconnect having a first width and lower portion connected to the backside power delivery network having a second width greater than the first width.

14. The semiconductor structure according to claim 12, wherein the electronic fuse via is connected to the back-end-of-the-line interconnect through a first conductive metal line of a metallization layer, and the electronic fuse via is connected to the backside power delivery network through a first backside power rail.

15. The semiconductor structure according to claim 14, further comprising another electronic fuse via having a negative tapered shape extending from the back-end-of-the-line interconnect to the backside power delivery network; wherein the other electronic fuse via comprises another conductive material.

16. The semiconductor structure according to claim 15, wherein the other electronic fuse via is connected to the back-end-of-the-line interconnect through a second conductive metal line of the metallization layer, and the other electronic fuse via is connected to the backside power delivery network through a second backside power rail.

17. The semiconductor structure according to claim 12, wherein the conductive material comprises a poly-Si, or silicided poly-Si material.

18. The semiconductor structure according to claim 12, wherein the electronic fuse via is co-integrated with a logic device through the backside power delivery network.

19. A semiconductor structure, comprising:
an electronic fuse via extending from a back-end-of-the-line interconnect to a backside power delivery network;
wherein the electronic fuse via comprises a conductive material; and
wherein the electronic fuse via comprises a void within the electronic fuse via.

20. The semiconductor structure according to claim 19, wherein the electronic fuse via is one of an electronic fuse via having a positive tapered shape extending from the back-end-of-the-line interconnect to the backside power delivery network and the void is located in proximity to the backside power delivery network, and an electronic fuse via having a negative tapered shape extending from the back-end-of-the-line interconnect to the backside power delivery network and the void is located in proximity to the back-end-of-the-line interconnect.
